(19) United States
(12) Patent Application Publication
(10) Pub. No.: US 2026/0013128 A1
(43) Pub. Date: Jan. 8, 2026

(54) MANUFACTURING METHOD OF SEMICONDUCTOR DEVICE

(71) Applicant: SK hynix Inc., Gyeonggi-do (KR)

(72) Inventors: Seong Man JEON, Gyeonggi-do (KR); Jun Hwi LEE, Gyeonggi-do (KR); Eun Yeoung CHOI, Gyeonggi-do (KR); Dong Chul YOO, Gyeonggi-do (KR)

(21) Appl. No.: 18/884,114

(22) Filed: Sep. 13, 2024

(30) Foreign Application Priority Data
Jul. 4, 2024 (KR) 10-2024-0088193

(51) Int. Cl. H10B 43/27

(52) U.S. Cl. CPC H10B 43/27

(57) ABSTRACT

A manufacturing method of a semiconductor device may include forming a stack; forming an opening in the stack, the opening having an elliptical shape with a major axis and a minor axis; forming a channel layer in the opening; forming an insulating layer over the channel layer; forming a barrier layer over the insulating layer; forming barrier patterns by etching the barrier layer, the barrier patterns being located on opposite sides on the major axis; increasing a thickness of the barrier patterns along the major axis; forming insulating patterns by etching the insulating layer using the barrier patterns as an etching barrier; and forming channel patterns by etching the channel layer using the insulating patterns as an etching barrier.

### CROSS-REFERENCE TO RELATED APPLICATION

This application claims priority under 35 U.S.C. § 119 to Korean Patent Application No. 10-2024-0088193 filed on Jul. 4, 2024, which is incorporated herein by reference in its entirety.

### BACKGROUND

### 1. Technical Field

Embodiments of the present disclosure relate to an electronic device, and more particularly, to a manufacturing method of a semiconductor device.

### 2. Related Art

The degree of integration of a semiconductor device is mainly determined by an area occupied by a unit memory cell. Recently, as improvements in the degree of integration of a semiconductor device for forming memory cells in a single layer on a substrate has been reaching a limit, a three-dimensional semiconductor device for stacking memory cells on a substrate has been considered. Furthermore, in order to improve the operational reliability of such a semiconductor device, various structures and manufacturing methods have been developed.

### SUMMARY

In one embodiment of the present disclosure, a manufacturing method of a semiconductor device may include forming a stack; forming an opening in the stack, the opening having an elliptical shape with a major axis and a minor axis; forming a channel layer in the opening; forming a first barrier layer over the channel layer; forming a barrier layer over the insulating layer; forming barrier patterns by etching the barrier layer, the barrier patterns being located on opposite sides on the major axis; increasing a thickness of the barrier patterns along the major axis; forming insulating patterns by etching the insulating layer using the barrier patterns as an etching barrier; and forming channel patterns by etching the channel layer using the insulating patterns as an etching barrier.

In another embodiment of the present disclosure, a manufacturing method of a semiconductor device may include forming a stack; forming an opening in the stack, the opening having an elliptical shape with a major axis and a minor axis; forming a data storage layer in the opening; forming a tunneling layer over the data storage layer; forming a channel layer over the tunneling layer;

forming a nitride barrier layer over the channel layer; forming an oxide barrier layer over the nitride barrier layer; forming barrier patterns over the oxide barrier layer, the barrier patterns being located on opposite sides on the major axis; forming oxide barrier patterns by etching the oxide barrier layer using the barrier patterns as an etching barrier; removing the barrier patterns to expose the oxide barrier patterns; forming nitride barrier patterns by etching the nitride barrier layer using the oxide barrier patterns as an etching barrier; and forming channel patterns by etching the channel layer using the oxide barrier patterns and the nitride barrier patterns as etching barriers.

### BRIEF DESCRIPTION OF THE DRAWINGS

FIGS. 1A to 1D are diagrams illustrating the structure of a semiconductor device in accordance with various embodiments of the present disclosure.

FIGS. 2A to 2H are diagrams for describing a manufacturing method of a semiconductor device in accordance with various embodiments of the present disclosure.

FIGS. 3A to 3J are diagrams for describing a manufacturing method of a semiconductor device in accordance with various embodiments of the present disclosure.

### DETAILED DESCRIPTION

Various embodiments of the present disclosure are directed to a manufacturing method of a semiconductor device having a stable structure and improved characteristics.

By stacking memory cells in three dimensions, it is possible to improve the degree of integration of a semiconductor device. It is also possible to provide a semiconductor device having a stable structure and improved reliability.

Hereafter, embodiments in accordance with the technical scope of the present disclosure will be described with reference to the accompanying drawings.

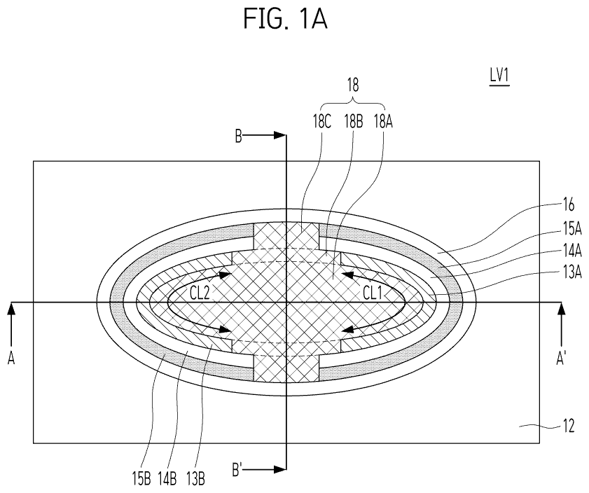

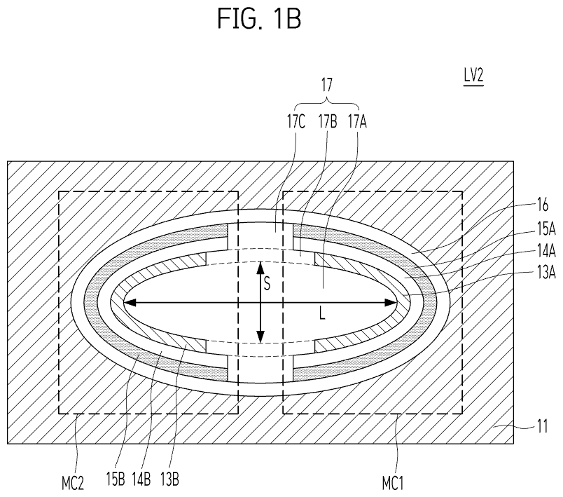

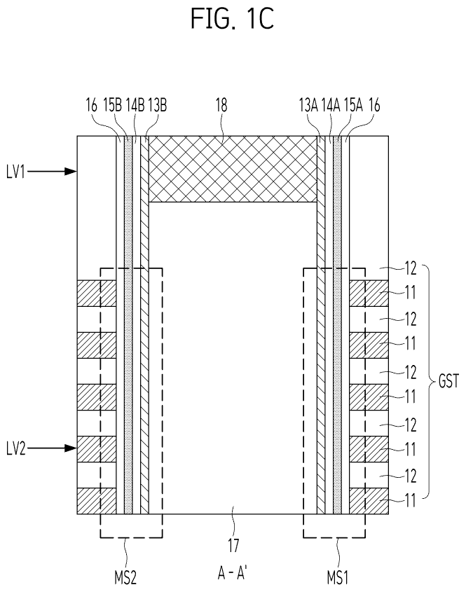

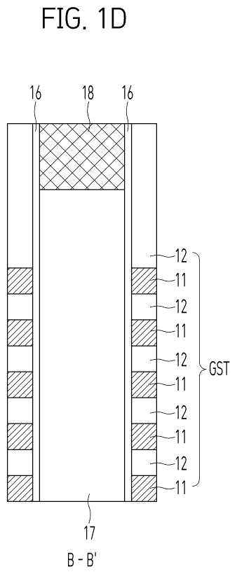

FIGS. 1A to 1D are diagrams illustrating the structure of a semiconductor device in accordance with one or more embodiments of the present disclosure. FIG. 1A is a plan view of a first level LV1 of FIG. 1C, FIG. 1B is a plan view of a second level LV2 of FIG. 1C, FIG. 1C is a cross-sectional view taken along line A-A′ of FIG. 1A, and FIG. 1D is a cross-sectional view taken along line B-B′ of FIG. 1A.

Referring to FIGS. 1A to 1D, the semiconductor device may include a gate structure GST, channel patterns 13A and 13B, tunneling patterns 14A and 14B, data storage patterns 15A and 15B, a blocking layer 16, an insulating core 17, and a channel pad 18.

The gate structure GST may include conductive layers 11 and insulating layers 12 that are alternately stacked as shown in FIG. 1C. The conductive layers 11 may be gate lines such as source select lines, word lines, or drain select lines. The conductive layers 11 may each include a conductive material such as polysilicon, tungsten, or molybdenum. The insulating layers 12 may be used to insulate the stacked conductive layers 11 from each other. The insulating layers 12 may each include oxide, nitride, air gap, or the like.

The insulating core 17 may extend through the gate structure GST as shown in FIG. 1C. The insulating core 17 may include a body portion 17A, a first protrusion portion 17B, and a second protrusion portion 17C as shown in FIG. 1B. In a plane defined by a first direction I and a second direction II intersecting the first direction I, the body portion 17A may have an elliptical shape. The body portion 17A may include a major axis L extending in the first direction I and a minor axis S extending in the second direction II. The first protrusion portion 17B may protrude from the body portion 17A and may extend along the minor axis S. The second protrusion portion 17C may protrude from the first protrusion portion 17B and may extend along the minor axis S.

The second protrusion portion 17C may have a smaller width than the first protrusion portion 17B.

The channel pad 18 may be located on the insulating core 17 and may have a similar structure to the insulating core 17 in a plan view. The channel pad 18 may include a body portion 18A, a first protrusion portion 18B, and a second protrusion portion 18C as shown in FIG. 1A. In a plan view, the body portion 18A may have an elliptical shape. The body portion 18A may include a major axis and a minor axis like the body portion 17A. The first protrusion portion 18B may protrude from the body portion 18A, and the second protrusion portion 18C may protrude from the first protrusion portion 18B. The second protrusion portion 18C may have a smaller width than the first protrusion portion 18B.

The channel patterns 13A and 13B may surround sidewalls of the insulating core 17 as shown in FIG. 1C. A first channel pattern 13A and a second channel pattern 13B may be located on opposite sides on the major axis L. The first channel pattern 13A may surround one end of the body portion 17A, and the second channel pattern 13B may surround the other end of the body portion 17A. The first channel pattern 13A and the second channel pattern 13B may be separated from each other by the first and second protrusion portions 17A and 17B.

The channel patterns 13A and 13B may surround sidewalls of the channel pad 18 as shown in FIG. 1A. The first channel pattern 13A may surround one end of the body portion 18A, and the second channel pattern 13B may surround the other end of the body portion 18A. The channel pad 18 may be commonly connected to the first channel pattern 13A and the second channel pattern 13B.

The tunneling patterns 14A and 14B may surround the channel patterns 13A and 13B as shown in FIG. 1A. The channel patterns 13A and 13B may each have a smaller length than the tunneling patterns 14A and 14B. A first tunneling pattern 14A may surround the first channel pattern 13A and the first protrusion portions 17B and 18B, and a second tunneling pattern 14B may surround the second channel pattern 13B and the first protrusion portions 17B and 18B. The first tunneling pattern 14A and the second tunneling pattern 14B may be separated from each other by the second protrusion portions 17C and 18C.

The data storage patterns 15A and 15B may surround the tunneling patterns 14A and 14B as shown in FIG. 1A. The data storage patterns 15A and 15B may each have substantially the same length as the tunneling patterns 14A and 14B. A first data storage pattern 15A may surround the first tunneling pattern 14A, and a second data storage pattern 15B may surround the second tunneling pattern 14B. The first data storage pattern 15A and the second data storage pattern 15B may be separated from each other by the second protrusion portions 17C and 18C. As an example, the data storage patterns 15A and 15B may each include a floating gate, polysilicon, a charge trap material, nitride, a variable resistance material, or the like.

The blocking layer 16 may surround the first data storage pattern 15A and the second data storage pattern 15B as shown in FIG. 1A. At the first level LV1, the blocking layer 16 may surround the first data storage pattern 15A, the second protrusion portion 18C, and the second data storage pattern 15B. At the second level LV2, the blocking layer 16 may surround the first data storage pattern 15A, the second protrusion portion 17C, and the second data storage pattern 15B.

According to the structure described above, the semiconductor device may include first memory cells MC1 stacked along the first channel pattern 13A and second memory cells MC2 stacked along the second channel pattern 13B as shown in FIG. 1C. The first memory cells MC1 may belong to a first memory string MS1, and the second memory cells MC2 may belong to a second memory string MS2. By locating the first memory string MS1 on one side of the insulating core 17 and locating the second memory string MS2 on the other side of the insulating core 17, it is possible to increase the degree of integration of a memory of the semiconductor device.

The first channel pattern 13A and the second channel pattern 13B may be separated from each other by the insulating core 17. The first channel pattern 13A may surround one end of the body portion 17A at a first length CL1, and the second channel pattern 13B may surround the other end of the body portion 17A at a second length CL2. By forming the first channel pattern 13A and the second channel pattern 13B to have greater lengths than conventional channel patterns, the first and second memory cells MC1 and MC2 may have a sufficient channel length and may be normally driven.

A sidewall of the first channel pattern 13A may be located to retreat compared to a sidewall of the first tunneling pattern 14A, and a sidewall of the second channel pattern 13B may be located to retreat compared to a sidewall of the second tunneling pattern 14B. That is the first and second channel patterns 13A and 13B do not extend as far as the first and second tunneling patterns 14A and 14B, and thus the channel patterns 13A and 13B have smaller lengths CL1, CL2 than any lengths of the tunneling patterns 14A and 14B along the elliptical shape of the memory device, and the channel patterns 13A and 13B are referred to herein as retreated channel patterns. Accordingly, direct leakage currents of the first and second memory cells MC1 and MC2 may be reduced.

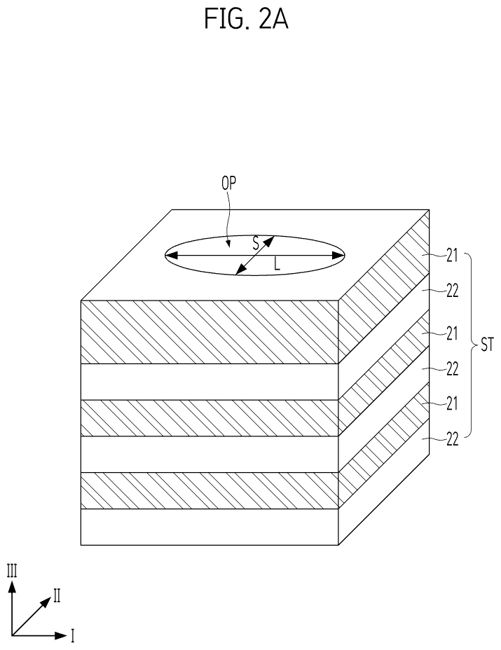

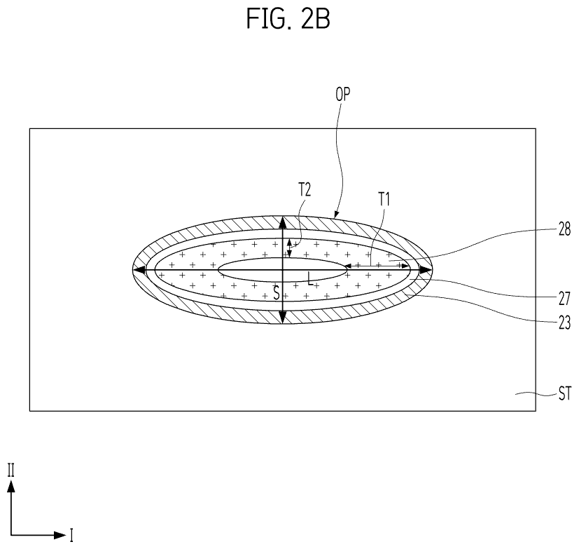

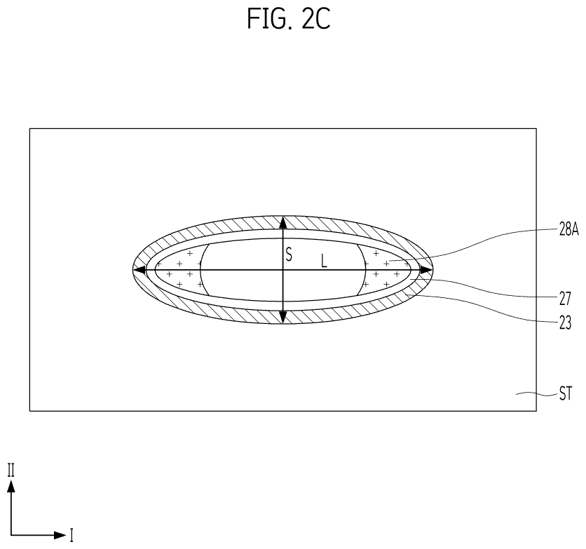

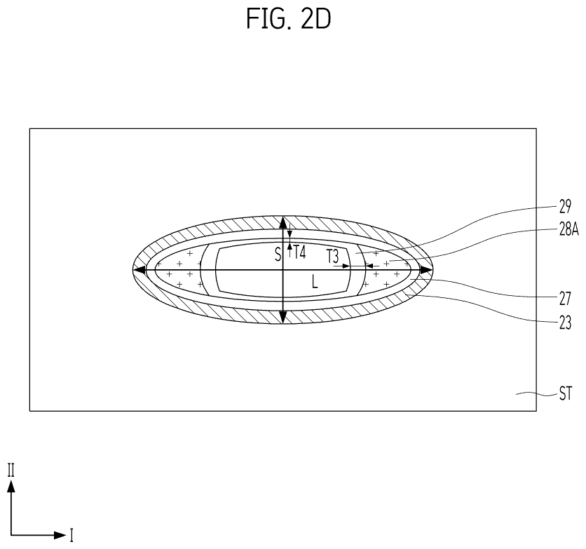

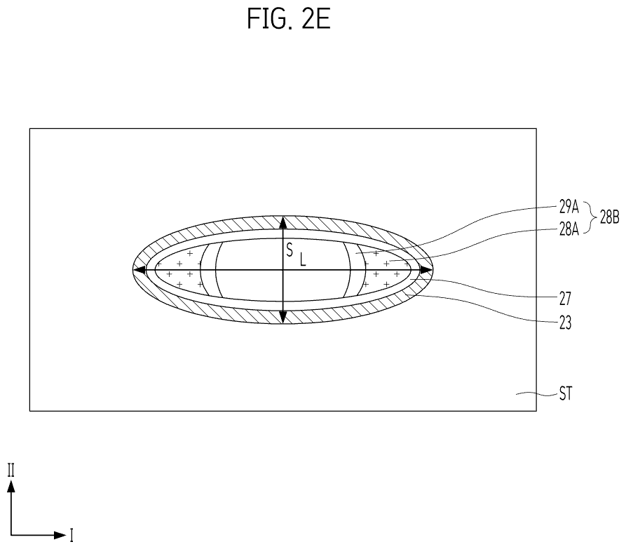

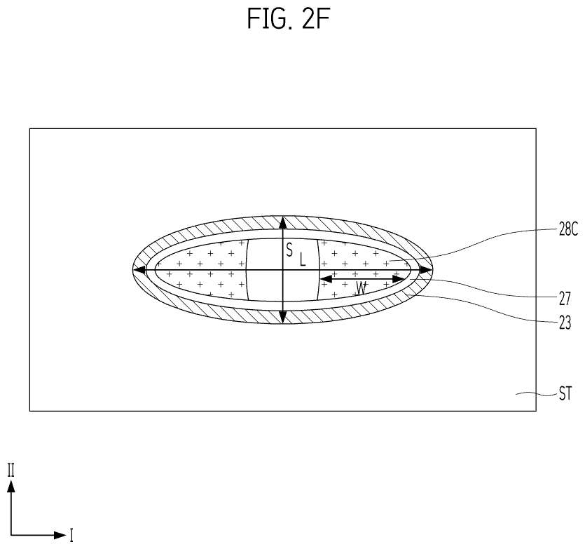

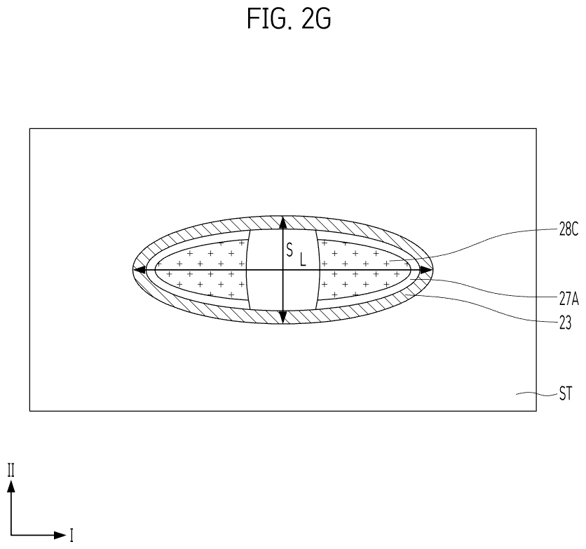

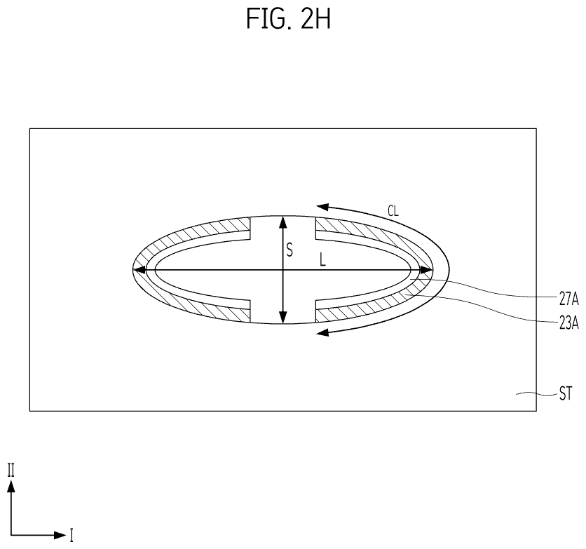

FIGS. 2A to 2H are diagrams for describing a manufacturing method of a semiconductor device in accordance with an embodiment of the present disclosure. FIG. 2A is a perspective view, and FIGS. 2B to 2H are plan views. Hereinafter, content overlapping with the previously described content may be omitted.

Referring to FIG. 2A, a stack ST may be formed. The stack ST may include first material layers 21 and second material layers 22 that are alternately stacked. The first material layers 21 may each include a material having a high etching selectivity with respect to the second material layers 22. The first material layers 21 may be used to form gate lines, and the second material layers 22 may be used to insulate the stacked gate lines from each other. The first material layers 21 may each include a sacrificial material such as nitride or a conductive material such as polysilicon or metal. The second material layers 22 may each include an insulating material such as oxide, nitride, or air gap.

Subsequently, an opening OP may be formed in the stack ST. The opening OP may be a channel hole. In the plane defined by the first direction I and the second direction II, the opening OP may have an elliptical shape. The opening OP may include a major axis L extending in the first direction I and a minor axis S extending in the second direction II. The opening OP may extend in a third direction III. The third direction III may be a direction perpendicular to the plane defined by the first direction I and the second direction II.

Referring to FIG. 2B, a channel layer 23 may be formed in the opening OP. The channel layer 23 may include a semiconductor material such as silicon or germanium. Subsequently, an insulating layer 27 may be formed over the channel layer 23. The insulating layer 27 may have a single-layer or multilayer structure. The insulating layer 27 may include a material having an etching selectivity with respect to the channel layer 23. As an example, the insulating layer 27 may include an oxide or a nitride.

Subsequently, a barrier layer 28 may be formed over the insulating layer 27. The barrier layer 28 may include a material having an etching selectivity with respect to the insulating layer 27. As an example, the barrier layer 28 may include polysilicon. The barrier layer 28 may have a first thickness T1 on the major axis L and may have a second thickness T2 on the minor axis S. The first thickness T1 and the second thickness T2 may be different from each other. A thickness difference may be caused by a difference in deposition environment between the major axis L and the minor axis S, and the first thickness T1 may be greater than the second thickness T2.

Referring to FIG. 2C, barrier patterns 28A may be formed by etching the barrier layer 28. As an example, the barrier layer 28 may be selectively etched using a wet etching process, and may be etched to expose the insulating layer 27. The insulating layer 27 may be exposed on the minor axis S where the barrier layer 28 is relatively thinly deposited, and exposed along the major axis L. The barrier patterns 28A may be formed on the major axis L where the barrier layer 28 is relatively thickly deposited. The barrier patterns 28A may be located on opposite sides on the major axis L, and may have a symmetrical shape with respect to the minor axis S.

Referring to FIGS. 2D to 2F, the barrier patterns 28A may be grown along a major axis L direction. The grown barrier patterns 28A may be used as an etching barrier for etching the channel layer 23.

First, referring to FIG. 2D, a barrier layer 29 may be additionally formed. As an example, the barrier layer 29 may be deposited by a low pressure chemical vapor deposition (LPCVD) method. The barrier layer 29 may be formed along surfaces of the insulating layer 27 and the barrier patterns 28A. Here, the insulating layer 27 and the barrier patterns 28A may have different incubation times. The incubation time refers to a time required for nucleation in a deposition process, and may change depending on a deposition surface and a material of a deposition layer. When the deposition surface and the deposition layer have similar chemical bonds, the incubation time may be short. When the insulating layer 27 is an oxide layer, the barrier patterns 28A are polysilicon layers, and the barrier layer 29 is a polysilicon layer, the incubation time may be shorter on surfaces of the barrier patterns 28A than on a surface of the insulating layer 27. Due to a difference in the incubation time, a speed at which the barrier layer 29 grows on the surfaces of the barrier patterns 28A may be greater than a speed at which the barrier layer 29 grows on the surface of the insulating layer 27.

Accordingly, the barrier layer 29 having different thicknesses on the major axis L and minor axis S may be formed using the difference in the incubation time between the insulating layer 27 and the barrier patterns 28A. The barrier layer 29 may have a fourth thickness T4 on the minor axis S and may have a third thickness T3 greater than the fourth thickness T4 on the major axis L.

Subsequently, referring to FIG. 2E, the barrier layer 29 may be etched to expose the insulating layer 27. The insulating layer 27 may be exposed on the minor axis S where the barrier layer 29 is a relatively thin deposit, and the barrier patterns 29A may be formed on the major axis L where the barrier layer 29 is a relatively thick deposit. As an example, the barrier layer 29 may be etched by a dry etching method using HBr gas or Cl₂ gas. By using the dry etching method, the barrier layer 29 may be etched to have a uniform thickness at an upper portion and a lower portion of the opening OP.

Through this, the barrier patterns 29A may be additionally formed. The barrier patterns 29A that are additionally formed may constitute barrier patterns 28B together with the barrier patterns 28A that are previously formed. As described above, by additionally depositing and etching the barrier layer 29, it is possible to increase a thickness of the barrier patterns 28B in the major axis L direction.

Subsequently, referring to FIG. 2F, deposition and etching processes of the barrier layer 29 may be repeatedly performed. Through this, barrier patterns 28C may be grown in the major axis L direction. By increasing the number of times of repetition, it is possible to increase a width W of the barrier patterns 28C as shown in FIG. 2F.

In repeatedly performing the deposition and etching processes, the number of times of repetition may be determined in consideration of a deposition time. In order to grow the barrier patterns 28C in the major axis L direction, it is advantageous for a difference between the third thickness T3 and the fourth thickness T4 to be great. However, as the deposition time of the barrier layer 29 increases, the difference between the third thickness T3 and the fourth thickness T4 may decrease. Accordingly, by increasing the number of times of repetition of the deposition and etching processes instead of decreasing the deposition time of the barrier layer 29, it is possible to form the barrier patterns 28C having a desired thickness.

Referring to FIG. 2G, insulating patterns 27A may be formed by etching the insulating layer 27 using the barrier patterns 28C as an etching barrier. Through this, the channel layer 23 may be exposed on the minor axis S.

Referring to FIG. 2H, the barrier patterns 28C may be removed. As an example, the barrier patterns 28C may be selectively etched. Subsequently, channel patterns 23A may be formed by etching the channel layer 23 using the insulating patterns 27A as an etching barrier.

According to the manufacturing method described above, by additionally forming the barrier patterns 29A using the difference in the incubation time, it is possible to form the barrier patterns 28C having a large width W. Accordingly, the channel patterns 23A separated from each other may be formed in the opening OP, and a length CL of the channel patterns 23A may be increased. Through this, memory cells having a sufficient channel length may be formed.

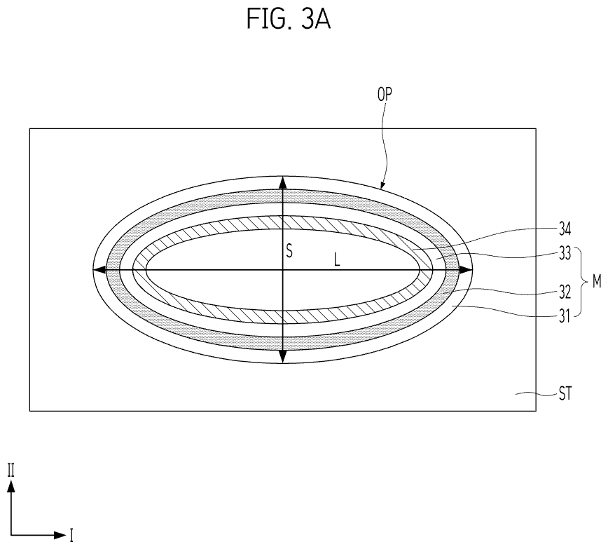

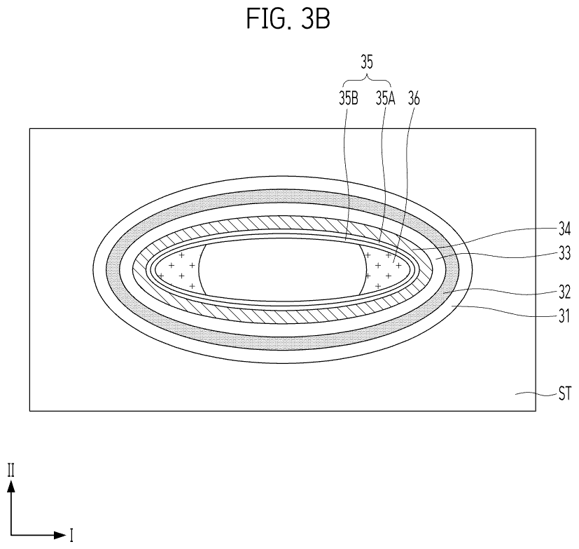

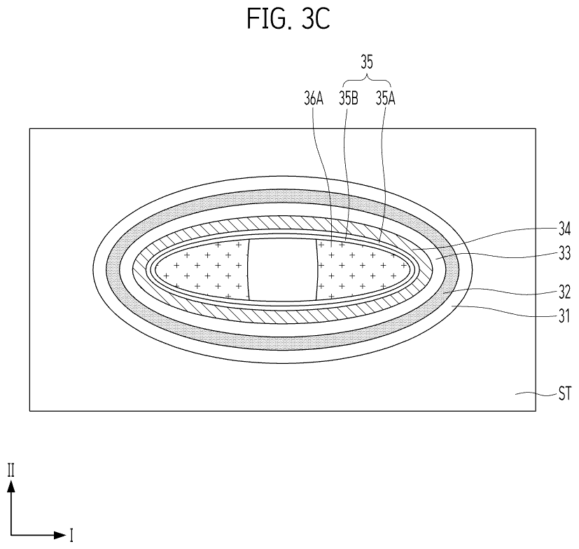

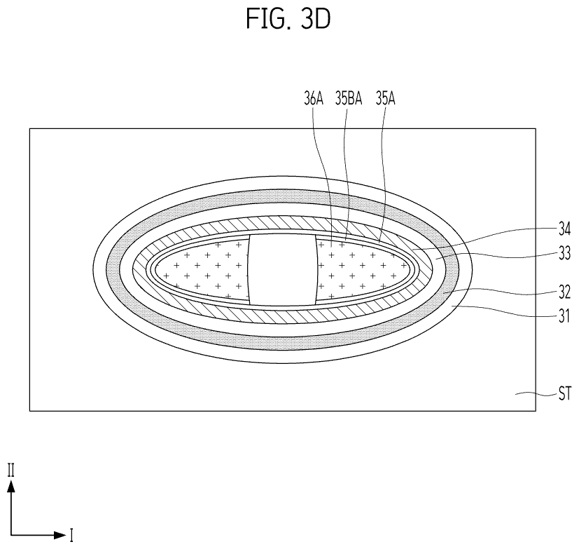

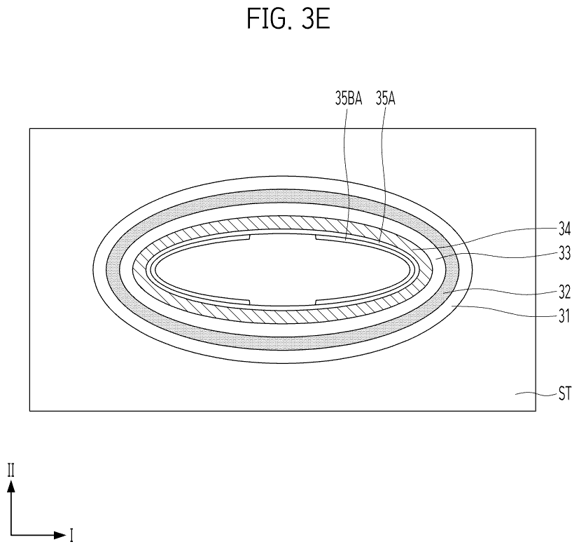

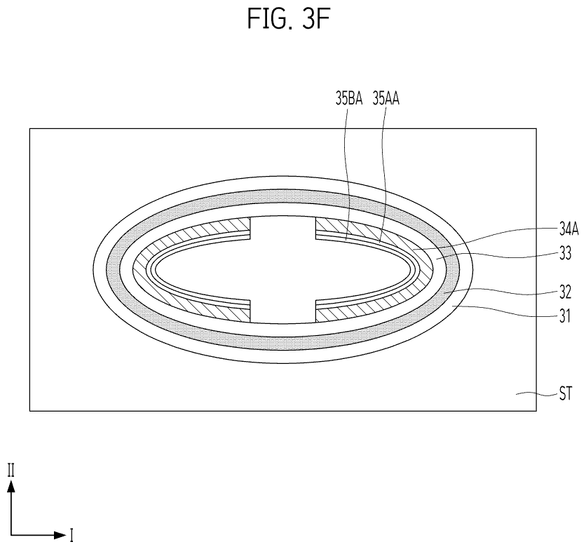

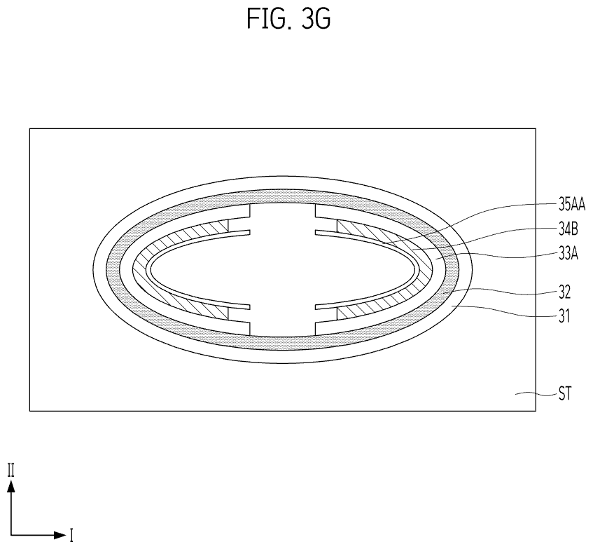

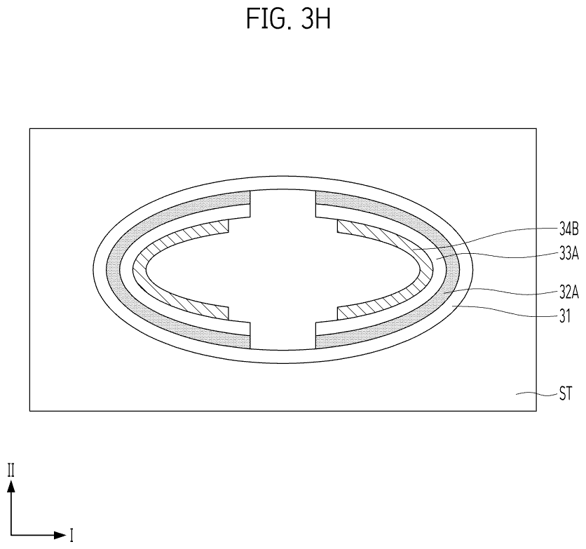

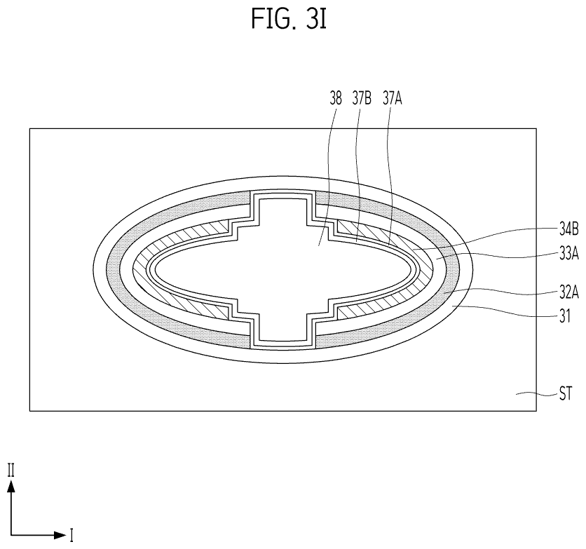

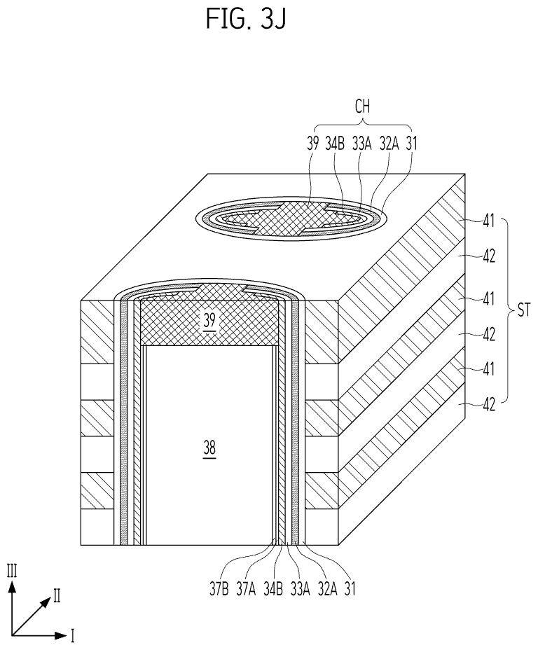

FIGS. 3A to 3J are diagrams for describing a manufacturing method of a semiconductor device in accordance with other embodiments of the present disclosure. FIGS. 3A to 3I are plan views, and FIG. 3J is a perspective view. Hereinafter, the content overlapping with the previously described content may be omitted.

Referring to FIG. 3A, an opening OP may be formed in a stack ST. As an example, the stack ST may include first material layers and second material layers that are alternately stacked. The opening OP may have an elliptical shape and may have a major axis L and a minor axis S. Subsequently, a memory layer M may be formed in the opening OP. The memory layer M may include at least one of a blocking layer 31, a data storage layer 32, and a tunneling layer 33. As an example, the blocking layer 31 may be formed in the opening OP, the data storage layer 32 may be formed over the blocking layer 31, and the tunneling layer 33 may be formed over the data storage layer 32. Subsequently, a channel layer 34 may be formed over the tunneling layer 33.

Referring to FIG. 3B, an insulating layer 35 may be formed over the channel layer 34. The insulating layer 35 may include a nitride layer 35A and an oxide layer 35B. As an example, the nitride layer 35A may be formed over the channel layer 34, and the oxide layer 35B may be formed over the nitride layer 35A.

Subsequently, barrier patterns 36 may be formed over the insulating layer 35. As an example, the barrier patterns 36 may be formed by forming a barrier layer in the insulating layer 35 and etching the barrier layer to expose the insulating layer 35. The barrier patterns 36 may be located on opposite sides on the major axis. The barrier patterns 36 may each include polysilicon. For example, the barrier patterns 36 are silicon-layer barrier patterns.

Referring to FIG. 3C, a thickness of the barrier patterns 36 may be increased along a major axis L direction. As an example, a barrier layer may be additionally formed along surfaces of the oxide layer 35B and the barrier patterns 36. In this case, a speed at which the barrier layer grows on the surfaces of the barrier patterns 36 may be greater than a speed at which the barrier layer grows on the surface of the oxide layer 35B. Subsequently, barrier patterns may be additionally formed by etching the barrier layer so that the oxide layer 35B is exposed. Subsequently, grown barrier patterns 36A may be formed by repeatedly performing a process of forming and etching the barrier layer.

Referring to FIG. 3D, oxide patterns 35BA may be formed by etching the oxide layer 35B using the barrier patterns 36A as an etching barrier. Through this, the nitride layer 35A may be exposed.

Referring to FIG. 3E, the barrier patterns 36A may be removed and the oxide patterns 35BA may be exposed. When the barrier patterns 36A are removed, the nitride layer 35A may function as a protective layer. When the nitride layer 35A does not exist, the barrier patterns 36A are removed in a state in which the channel layer 34 is exposed. In such a case, the channel layer 34 may be damaged in a process of removing the barrier patterns 36A. To address this issue, in one embodiment, the nitride layer 35A includes a material having a high etching selectivity with respect to the barrier patterns 36A, and may thus protect the channel layer 34.

Referring to FIG. 3F, nitride patterns 35AA may be formed by etching the nitride layer 35A using the oxide patterns 35BA as an etching barrier. Subsequently, channel patterns 34A may be formed by etching the channel layer 34 using the oxide patterns 35BA and the nitride patterns 35AA as etching barriers. Through this, the tunneling layer 33 may be exposed.

Referring to FIG. 3G, tunneling patterns 33A may be formed by etching the tunneling layer 33 using the nitride patterns 35AA as an etching barrier. When the tunneling layer 33 is etched, the oxide patterns 35BA may be removed. As the oxide patterns 35BA are removed, the nitride patterns 35AA may be exposed.

Subsequently, the channel patterns 34A may be etched using the nitride patterns 35AA and the tunneling patterns 33A as etching barriers. Sidewalls of the etched channel patterns 34B may be located to retreat compared to sidewalls of the tunneling patterns 33A such that channel patterns 34B have a smaller length than the tunneling patterns 33A.

Referring to FIG. 3H, data storage patterns 32A may be formed by etching the data storage layer 32 using the tunneling patterns 33A as an etching barrier. When the data storage layer 32 is etched, the nitride barrier patterns 35AA may be removed. Sidewalls of the data storage patterns 32A may be aligned with the sidewalls of the tunneling patterns 33A.

Referring to FIG. 3I, an insulating core 38 may be formed over the channel patterns 34B. The insulating core 38 may be used to fill the opening OP, and may include polysilazane (PSZ). Before the insulating core 38 is formed, a first liner layer 37A and a second liner layer 37B may be formed on the channel patterns 34B. As an example, the first liner layer 37A may be formed over the channel patterns 34B, and the second liner layer 37B may be formed over the first liner layer 37A. The first liner layer 37A and the second liner layer 37B may be used to protect the channel patterns 34B, the tunneling patterns 33A, the data storage patterns 32A, and the blocking layer 31 in a subsequent process. The second liner layer 37B may include a material having a high etching selectivity with respect to the insulating core 38, and may include a high dielectric constant material such as aluminum oxide (Al₂O₃). The first liner layer 37A may include a material having a high etching selectivity with respect to the second liner layer 37B, and may include oxide.

Referring to FIG. 3J, the insulating core 38 may be partially etched. When the insulating core 38 is etched, the first liner layer 37A and the second liner layer 37B may protect the channel patterns 34B, the tunneling patterns 33A, the data storage patterns 32A, and the blocking layer 31. Subsequently, the second liner layer 37B and the first liner layer 37A may be etched. When the second liner layer 37B is etched, the first liner layer 37A may protect the channel patterns 34B, the tunneling patterns 33A, the data storage patterns 32A, and the blocking layer 31. Through this, upper inner walls of the channel patterns 34B may be exposed.

Subsequently, a channel pad 39 may be formed over the channel patterns 34B. The channel pad 39 may be located over the insulating core 38 and connected to channel patterns 34B. Through this, a channel structure CH extending through the stack ST may be formed.

Subsequently, the first material layers 41 of the stack ST may be replaced with conductive layers. Through this, a gate structure including the conductive layers and the second material layers 42 that are alternately stacked may be formed. For reference, when the first material layers 41 each include a conductive material, a process of replacing the first material layers 41 with the conductive layers may be omitted. In such a case, the first material layers 41 may be used as gate lines, and the stack ST may be used as the gate structure.

According to the manufacturing method described above, by growing the barrier patterns 36A in the major axis L direction, it is possible to increase a length of the channel pattern 34A. By forming the insulating layer 35 as a double layer (35AA, 35BA) as shown in FIG. 3F, it is possible to prevent the channel layer 34 from being damaged in a manufacturing process.

Although embodiments according to the technical scope of the present disclosure have been described above with reference to the accompanying drawings, this is only for describing the embodiments according to the concept of the present disclosure, and the present disclosure is not limited to the above embodiments. Various types of substitutions, modifications, changes, and combinations for the embodiments may be made by those skilled in the art, to which the present disclosure pertains, without departing from the technical scope of the present disclosure, and it should be construed that these substitutions, modifications, changes, and combinations belong to the scope of the present disclosure. Furthermore, the embodiments may be combined to form additional embodiments.

What is claimed is:

1. A manufacturing method of a semiconductor device, the manufacturing method comprising:
forming a stack;
forming an opening in the stack, the opening having an elliptical shape with a major axis and a minor axis;
forming a channel layer in the opening;
forming an insulating layer over the channel layer;
forming a barrier layer over the insulating layer;
forming barrier patterns by etching the barrier layer, the barrier patterns being located on opposite sides on the major axis;
increasing a thickness of the barrier patterns along the major axis;
forming insulating patterns by etching the insulating layer using the barrier patterns as an etching barrier; and
forming channel patterns by etching the channel layer using the insulating patterns as an etching barrier.

2. The manufacturing method of claim 1, wherein the increasing of the thickness of the barrier patterns comprises:
forming a subsequent barrier layer along surfaces of the insulating layer and the barrier patterns; and
etching the subsequent barrier layer to expose the insulating layer.

3. The manufacturing method of claim 2, wherein forming the subsequent barrier layer and the etching the subsequent barrier layer are repeatedly performed.

4. The manufacturing method of claim 2, wherein in forming the subsequent barrier layer, a speed at which the subsequent barrier layer grows on the surfaces of the barrier patterns is greater than a speed at which the barrier layer grows on the surface of the insulating layer.

5. The manufacturing method of claim 1, wherein forming the insulating layer comprises:
forming a nitride layer over the channel layer; and
forming an oxide layer over the nitride layer.

6. The manufacturing method of claim 5, wherein the barrier layer includes polysilicon.

7. The manufacturing method of claim 5, wherein forming the insulating patterns comprises:
forming oxide patterns by etching the oxide layer using the barrier patterns as an etching barrier;
removing the barrier patterns; and
forming nitride patterns by etching the nitride layer using the oxide patterns as an etching barrier.

8. The manufacturing method of claim 7, wherein when the barrier patterns are removed, the channel layer is protected by the nitride layer.

9. The manufacturing method of claim 7, further comprising etching the channel patterns using the nitride patterns as an etching barrier.

10. The manufacturing method of claim 1, further comprising forming a channel pad connected to the channel patterns.

11. A manufacturing method of a semiconductor device, the manufacturing method comprising:
forming a stack;
forming an opening in the stack, the opening having an elliptical shape with a major axis and a minor axis;
forming a data storage layer in the opening;
forming a tunneling layer over the data storage layer;
forming a channel layer over the tunneling layer;
forming a nitride layer over the channel layer;
forming an oxide layer over the nitride layer;
forming barrier patterns over the oxide layer, the barrier patterns being located on opposite sides on the major axis;
forming oxide patterns by etching the oxide layer using the barrier patterns as a first etching barrier;
removing the barrier patterns to expose the oxide patterns;
forming nitride patterns by etching the nitride layer using the oxide patterns as an etching barrier; and
forming channel patterns by etching the channel layer using the oxide patterns and the nitride patterns as etching barriers.

12. The manufacturing method of claim 11, further comprising increasing a thickness of the barrier patterns along the major axis.

13. The manufacturing method of claim 12, wherein increasing the thickness of the barrier patterns comprises:
forming a subsequent barrier layer along surfaces of the oxide layer and the barrier patterns; and
etching the subsequent barrier layer to expose the oxide layer, and
forming the subsequent barrier layer and etching the subsequent barrier layer are repeatedly performed.

14. The manufacturing method of claim 13, wherein in forming the subsequent barrier layer, a speed at which the subsequent barrier layer grows on the surfaces of the barrier patterns is greater than a speed at which the barrier layer grows on the surface of the oxide barrier layer.

15. The manufacturing method of claim 11, wherein when the barrier patterns are removed, the channel layer is protected by the nitride layer.

16. The manufacturing method of claim 11, further comprising forming tunneling patterns by etching the tunneling layer using the nitride patterns as an etching barrier.

17. The manufacturing method of claim 16, wherein when the tunneling layer is etched, the oxide patterns are removed.

18. The manufacturing method of claim 17, further comprising etching the channel patterns using the nitride patterns and the tunneling patterns as etching barriers.

19. The manufacturing method of claim 16, further comprising forming data storage patterns by etching the data storage layer using the tunneling patterns as an etching barrier.

20. The manufacturing method of claim 19, wherein when the data storage layer is etched, the nitride barrier patterns are removed.

21. The manufacturing method of claim 11, further comprising forming a channel pad connected to the channel patterns.

22. A manufacturing method of a semiconductor memory device having a split channel, the manufacturing method comprising:
forming a stack;
forming an opening in the stack, the opening having an elliptical shape with a major axis and a minor axis;
forming a data storage layer in the opening;
forming a tunneling layer over the data storage layer;
forming a channel layer over the tunneling layer;
forming a nitride layer over the channel layer;
forming an oxide layer over the nitride layer;
forming silicon-layer barrier patterns on the oxide layer, the silicon-layer barrier patterns being located on opposite sides on the major axis;
forming oxide patterns by etching the oxide layer using the silicon-layer barrier patterns as a first etching barrier;
removing the silicon-layer barrier patterns to expose the oxide patterns;
forming nitride patterns by etching the nitride layer using the oxide patterns as a second etching barrier;
splitting the channel layer and the tunneling layer by etching the channel layer and the tunneling layer using the oxide patterns and the nitride patterns as a third etching barrier to form two channel layers and two tunneling layers; and
splitting the data storage layer by etching the data storage layer using the two tunneling layers as a third etching barrier to form two data storage layers,
wherein the two channels comprise the split channel, and both of the two channels have a length along the elliptical shape of the semiconductor memory device which is less than any lengths of the two data storage layers and the two tunneling layers along the elliptical shape of the semiconductor memory device.
